(19) United States
(12) Patent Application Publication
(10) Pub. No.: US 2026/0112439 A1
(43) Pub. Date: Apr. 23, 2026

(54) STORAGE CONTROLLER FOR DETECTING FAILURE OF NONVOLATILE MEMORY DEVICE, STORAGE DEVICE INCLUDING THE STORAGE CONTROLLER, AND ELECTRONIC SYSTEM INCLUDING THE STORAGE DEVICE

(71) Applicant: Samsung Electronics Co., Ltd., Suwon-si (KR)

(72) Inventors: Unseon Cho, Suwon-si (KR); JINGEUN PARK, Suwon-si (KR); HUI SUB SHIM, Suwon-si (KR); SUKHEE LEE, Suwon-si (KR); Seungmin Lee, Suwon-si (KR); DONGHWAN JEONG, Suwon-si (KR); Joonyong Jeong, Suwon-si (KR); KEUNJAE LEE, Suwon-si (KR); Hyejin Jang, Suwon-si (KR)

(21) Appl. No.: 19/329,491

(22) Filed: Sep. 15, 2025

(30) Foreign Application Priority Data
Oct. 23, 2024 (KR) 10-2024-0146003

(51) Int. Cl. G11C 29/44

(52) U.S. Cl. CPC G11C 29/44

(57) ABSTRACT

A storage device according to the present disclosure includes a plurality of nonvolatile memory devices including a plurality of memory blocks, and a storage controller connected to the plurality of nonvolatile memory devices. The storage controller may detect a bad block among the memory blocks, generate a first level fail signal based on the number of bad blocks of a first nonvolatile memory device, generate a second level fail signal based on the number of reserved free blocks included in the remaining nonvolatile memory devices, generate a third level fail signal based on the number of memory blocks including error bits greater than a preset number of error bits among memory blocks included in the first nonvolatile memory device, and provide the first level fail signal, the second level fail signal, or the third level fail signal to a host.

### CROSS-REFERENCE TO RELATED APPLICATION(S)

This application claims priority to and the benefit of Korean Patent Application No. 10-2024-0146003, filed in the Korean Intellectual Property Office on Oct. 23, 2024, the disclosure of which is incorporated herein by reference in its entirety.

### BACKGROUND

### (a) Field

The present disclosure relates to a storage controller for detecting a failure of a nonvolatile memory device, a storage device including the storage controller, and an electronic system including the storage device.

### (b) Description of the Related Art

Storage devices, including nonvolatile memory devices, are devices that store data. Among the nonvolatile memory devices, there may be fail nonvolatile memory devices that become unusable over time. Since failure of a nonvolatile memory device reduces a storage device capacity, it is necessary to accurately detect the failure of the nonvolatile memory device.

### SUMMARY

Embodiments attempt to provide a storage controller for detecting a degree of failure of a nonvolatile memory device in stages, a storage device including the storage controller, and an electronic system including the storage device.

According to an embodiment of the present disclosure, a storage device may include a plurality of nonvolatile memory devices including a plurality of memory blocks, and a storage controller connected to the plurality of nonvolatile memory devices. The storage controller may detect a bad block among the memory blocks, generate a first level fail signal indicating that a degree of failure of a first nonvolatile memory device including the bad block among the plurality of nonvolatile memory devices is in a first level based on the number of bad blocks of the first nonvolatile memory device, generate a second level fail signal indicating that the degree of failure of the first nonvolatile memory device is in a second level that is higher than the first level based on the number of reserved free blocks, which are free blocks, among reserved blocks included in the remaining nonvolatile memory devices, generate a third level fail signal indicating that the degree of failure of the first nonvolatile memory device is in a third level that is higher than the second level based on the number of memory blocks including error bits greater than a preset number of error bits among memory blocks included in the first nonvolatile memory device, and provide the first level fail signal, the second level fail signal, or the third level fail signal to a host outside the storage device.

According to an embodiment of the present disclosure, an electronic system may include a host and a storage device connected to the host and including a plurality of nonvolatile memory devices. The storage device may output a first level fail signal indicating that a possibility of failure of a first nonvolatile memory device among the plurality of nonvolatile memory devices is in a first level when the number of bad blocks included in the first nonvolatile memory device is greater than the number of reserved blocks included in the first nonvolatile memory device, output a second level fail signal indicating that the possibility of failure of the first nonvolatile memory device is in a second level higher than the first level when the number of reserved free blocks included in the remaining nonvolatile memory devices among the plurality of nonvolatile memory devices is less than a first preset number of blocks, and output a third level fail signal indicating that the possibility of failure of the first nonvolatile memory device is in a third level higher than the second level when the number of memory blocks including more error bits than a preset number of error bits among memory blocks included in the first nonvolatile memory device is greater than a second preset number of blocks different from the first preset number of blocks. The host may control the storage device based on the first level fail signal, the second level fail signal, or the third level fail signal.

According to an embodiment of the present disclosure, a storage controller may include a memory interface configured to communicate with a plurality of nonvolatile memory devices including a plurality of memory blocks, and a bad block management module connected to the plurality of nonvolatile memory devices. The bad block management module may detect a bad block among the plurality of memory blocks, copy data stored in the bad block to reserved free blocks of the remaining nonvolatile memory devices among the plurality of nonvolatile memory devices when the number of bad blocks of a first nonvolatile memory device including the bad block among the plurality of nonvolatile memory devices is greater than the number of reserved blocks of the first nonvolatile memory device, set the bad block as a read-only block when the number of reserved free blocks of the remaining volatile memory devices is less than a first threshold number, and set a mode of the first nonvolatile memory device to a read-only mode or a fail mode when the number of memory blocks including more error bits than a preset number of error bits among memory blocks included in the first nonvolatile memory device is greater than a second threshold number.

### BRIEF DESCRIPTION OF THE DRAWINGS

FIG. 1 illustrates a view for describing an electronic system including a storage device according to an embodiment.

FIG. 2 illustrates a storage device that copies data stored in a bad block to a reserved block according to an embodiment.

FIG. 3 illustrates a storage device that copies data stored in a bad block of one nonvolatile memory device to a reserved block of another nonvolatile memory device according to an embodiment.

FIG. 4 illustrates a view for describing a storage controller that provides a first level fail signal to a host based on the number of reserved blocks included in a plurality of nonvolatile memory devices according to an embodiment.

FIG. 5 illustrates a view for describing a storage controller that provides a second level fail signal to the host based on the number of reserved blocks included in a plurality of nonvolatile memory devices according to an embodiment.

FIG. 6 illustrates a view for describing a storage controller that provides a third level fail signal to the host based on a number of error bits included in memory blocks of a nonvolatile memory device according to an embodiment.

FIG. 7 illustrates a view for describing a stripe block included in one nonvolatile memory device according to an embodiment.

FIG. 8 illustrates a flowchart showing a storage device providing a first level fail signal and a second level fail signal to the host according to an embodiment.

FIG. 9 illustrates a flowchart showing a storage device providing a third level fail signal to the host according to an embodiment.

FIG. 10 illustrates a view for describing a nonvolatile memory device according to an embodiment.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

To clearly describe the present disclosure, parts that are irrelevant to the description are omitted, and like numerals refer to like or similar components throughout the specification.

In addition, unless explicitly described to the contrary, the word “comprise” and variations such as “comprises” or “comprising” will be understood to imply the inclusion of stated elements but not the exclusion of any other elements.

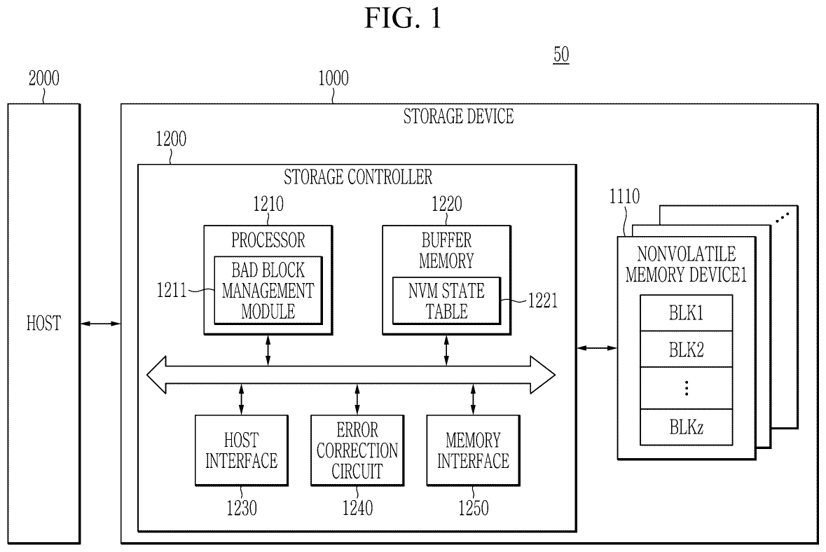

FIG. 1 illustrates a view for describing an electronic system 50 including a storage device 1000 according to an embodiment.

Referring to FIG. 1, the electronic system 50 may include the storage device 1000 and a host 2000.

The storage device 1000 may be a device that stores data under control of the host 2000. In an embodiment, the storage device 1000 may be manufactured in a form of a solid state drive (SSD) or a universal flash storage (UFS).

In an embodiment, the storage device 1000 may include a plurality of nonvolatile memory devices and a storage controller 1200.

In an embodiment, a first nonvolatile memory device 1110 among the nonvolatile memory devices may store data. The first nonvolatile memory device 1110 may operate in response to the control of the storage controller 1200. In an embodiment, the first nonvolatile memory device 1110 may be a NAND flash memory. The first nonvolatile memory device 1110 may include a plurality of memory blocks BLK1 to BLKz (herein, z is a natural number of 2 or greater). Each of the memory blocks BLK1 to BLKz may include a plurality of memory cells that store data. In an embodiment, the memory blocks BLK1 to BLKz may include normal blocks and reserved blocks. In an embodiment, a reserved block may be a memory block that replaces a memory block detected as a bad block among the normal blocks. In an embodiment, the normal blocks may be memory blocks that store user data received from the host 2000 and metadata related to the user data.

In an embodiment, the nonvolatile memory device 1110 may receive a command and an address from the storage controller 1200, and may perform an operation indicated by the command for a region selected by the address. The first nonvolatile memory device 1110 may perform a program operation (write operation) for storing data in a region selected by an address, a read operation for reading data, or an erase operation for deleting data.

The storage controller 1200 may control a general operation of the storage device 1000.

In an embodiment, the storage controller 1200 may execute firmware when power is applied to the storage device 1000. The firmware may include a host interface layer that controls communication with the host 2000, a flash translation layer that controls communication between the host 2000 and the nonvolatile memory devices, and a memory interface layer that controls communication with the nonvolatile memory devices. In an embodiment, the flash translation layer may translate a logical address of the host 2000 into a physical address of the nonvolatile memory devices.

In an embodiment, the storage controller 1200 may control a plurality of nonvolatile memory devices to perform a write operation, a read operation, or an erase operation, etc., according to a request of the host 2000. The storage controller 1200 may provide the write command, an address, and data to the nonvolatile memory devices during the write operation. The storage controller 1200 may provide the read command and an address to the nonvolatile memory devices during the read operation. The storage controller 1200 may provide the erase command and an address to the nonvolatile memory devices during the erase operation.

In an embodiment, the storage controller 1200 may include a processor 1210, a buffer memory 1220, a host interface 1230, an error correction circuit 1240, and a memory interface 1250.

In an embodiment, the processor 1210 may control a general operation of the storage controller 1200. The processor 1210 may generate a write command in response to a write request from the host 2000 and a read command in response to a read request from the host 2000.

In an embodiment, the processor 1210 may include a bad block management module 1211. In an embodiment, the bad block management module 1211 may detect one memory block among the memory blocks included in the nonvolatile memory devices as a bad block.

In an embodiment, when a program operation for one of the memory blocks fails, the bad block management module 1211 may detect the one memory block as a bad block.

In an embodiment, the bad block management module 1211 may detect a memory block including more error bits than a preset number of error bits among the memory blocks as a bad block.

In an embodiment, when an erase operation for one of the memory blocks fails, the bad block management module 1211 may detect the one memory block as a bad block.

In an embodiment, the bad block management module 1211 may detect a bad block among the memory blocks included in the nonvolatile memory devices, and may provide a fail signal to the host 2000 indicating a degree of failure of the nonvolatile memory device including the detected bad block, based on the number of bad blocks of the nonvolatile memory device including the detected bad block among the nonvolatile memory devices, the number of reserved free blocks, which are free blocks, among the reserved blocks of the memory blocks included in the nonvolatile memory devices, and the number of memory blocks including error bits that is greater than the preset number of error bits among the memory blocks of the nonvolatile memory device including the detected bad block.

In an embodiment, the bad block management module 1211 may copy data stored in the detected bad block to a reserved block of the nonvolatile memory device including the detected bad block if the number of bad blocks of the nonvolatile memory device including the detected bad block is less than the number of reserved blocks of the nonvolatile memory device including the detected bad block.

In an embodiment, if the number of bad blocks of the nonvolatile memory device including the detected bad block is greater than the number of reserved blocks of the nonvolatile memory device including the detected bad block, and the number of reserved blocks of the remaining nonvolatile memory devices excluding the nonvolatile memory device including the detected bad block among the nonvolatile memory devices is larger than a first preset number of blocks, the bad block management module 1211 may provide a first level fail signal to the host 2000 indicating that the degree of failure of the nonvolatile memory device including the detected bad block is in a first level.

In an embodiment the bad block management module 1211 may copy data stored in the detected bad block to a reserved block of another nonvolatile memory device if the number of bad blocks of the nonvolatile memory device including the detected bad block is greater than the number of reserved blocks of the nonvolatile memory device including the detected bad block.

In an embodiment, if the number of reserved blocks of the remaining nonvolatile memory devices excluding the nonvolatile memory device including the detected bad block among the nonvolatile memory devices is less than the first preset number of blocks, the bad block management module 1211 may provide a second level fail signal to the host 2000 indicating that the degree of failure of the nonvolatile memory device including the detected bad block is in a second level that is higher than the first level.

In an embodiment, if the number of memory blocks including more error bits than the preset number of error bits among the memory blocks of the nonvolatile memory device including the detected bad block is greater than the preset number of error bits, the bad block management module 1211 may provide a third level fail signal to the host 2000 indicating that the degree of failure of the nonvolatile memory device including the detected bad block is in a third level.

In an embodiment, the bad block management module 1211 may copy data stored in the nonvolatile memory device including the detected bad block to remaining nonvolatile memory devices if the number of memory blocks including error bits greater than the preset number of error bits among the memory blocks of the nonvolatile memory device including the detected bad block is greater than the first preset number of blocks.

In an embodiment, the buffer memory 1220 may be used as a cache memory or an operating memory of the storage controller 1200.

In an embodiment, the buffer memory 1220 may temporarily store data provided from the host 2000, or may temporarily store data read from a nonvolatile memory device (e.g., the first nonvolatile memory device 1110). In an embodiment, the buffer memory 1220 may be a dynamic random access memory (DRAM) or a static random access memory (SRAM). In an embodiment, the buffer memory 1220 may be positioned within the storage controller 1200 or may be positioned outside the storage controller 1200.

In an embodiment, the buffer memory 1220 may store an NVM state table 1221.

In an embodiment, the NVM state table 1221 may include information related to an operation mode of each of the nonvolatile memory devices and information related to a state of each of the memory blocks included in the nonvolatile memory devices. In an embodiment, information regarding the operational mode of each of the nonvolatile memory devices may include information regarding a normal mode, a read-only mode, or a failure mode.

In an embodiment, the normal mode may be a mode in which the nonvolatile memory device may perform a program operation, a read operation, and an erase operation. In an embodiment, the read-only mode may be a mode in which the nonvolatile memory device may only perform the read operation. In an embodiment, the failure mode may be a mode in which the nonvolatile memory device is unusable.

In an embodiment, information related to a state of each of the memory blocks may include information indicating that each of the memory blocks is a bad block, a normal block, or a read-only block.

In an embodiment, the host interface 1230 may communicate with the host 2000. The host interface 1230 may receive data from the host 2000, or may provide data to the host 2000.

In an embodiment, the error correction circuit 1240 may perform an encoding operation to generate parity data for data received from the host 2000. The encoded data may be provided to the first nonvolatile memory device 1110 via the memory interface 1250. The error correction circuit 1240 may perform an error correction operation on data read from the first nonvolatile memory device 1110. The error correction circuit 1240 may perform an error correction operation to correct error bits included in data read from the first nonvolatile memory device 1110. The error correction circuit 1240 may provide error-corrected data to the host 2000 through the host interface 1230.

In an embodiment, the memory interface 1250 may communicate with the first nonvolatile memory device 1110. The memory interface 1250 may provide data to the first nonvolatile memory device 1110, or may receive data from the first nonvolatile memory device 1110.

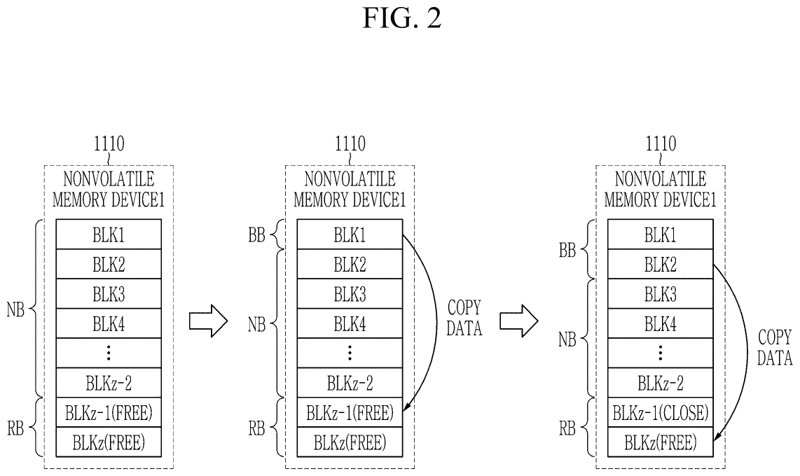

FIG. 2 illustrates a storage device that copies data stored in a bad block to a reserved block according to an embodiment.

Referring to FIG. 2, the first nonvolatile memory device 1110 may include a plurality of memory blocks BLK1 to BLKz. In an embodiment, some of the memory blocks BLK1 to BLKz may be normal blocks NB, and other memory blocks may be reserved blocks RB. In an embodiment, the number of reserved blocks RB of the first nonvolatile memory device 1110 may be two.

In an embodiment, among the memory blocks BLK1 to BLKz, first to (z-2)^{th} memory blocks BLK1 to BLK(z-2) may correspond to normal blocks NB. In an embodiment, among the memory blocks BLK1 to BLKz, (z-1)^{th} to z^{th} memory blocks BLK(z-1) to BLKz may correspond to reserved blocks RB.

In an embodiment, the reserved block RB may be a block that replaces a bad block BB. In an embodiment, the reserved block RB before replacing the bad block BB may be a reserved free block. The reserved free block may be a free block FREE that does not have any data stored.

In an embodiment, the bad block management module 1211 may detect one memory block among the memory blocks BLK1 to BLKz included in the first nonvolatile memory device 1110 as a bad block BB, and may control the first nonvolatile memory device 1110 to copy data stored in the bad block BB to the reserved block RB based on a result of comparing the number of bad blocks BB of the first nonvolatile memory device 1110 with the number of reserved blocks RB.

In an embodiment, the bad block management module 1211 may control the first nonvolatile memory device 1110 to copy data stored in the detected bad block BB to the reserved block RB when the number of bad blocks BB of the first nonvolatile memory device 1110 is equal to or less than the number of reserved blocks RB.

In an embodiment, the bad block management module 1211 may detect a first memory block BLK1 among the memory blocks BLK1 to BLKz included in the first nonvolatile memory device 1110 as the bad block BB.

In an embodiment, if the number of bad blocks BB of the first nonvolatile memory device 1110 is 1 and the number of reserved blocks RB is 2, the bad block management module 1211 may control the first nonvolatile memory device 1110 to copy data stored in the first memory block BLK1 corresponding to the bad block BB to the (z-1)^{th} memory block BLK(z-1) corresponding to the reserved block RB. In an embodiment, when data of the first memory block BLK1 is copied to the (z-1)^{th} memory block BLK(z-1), the (z-1)^{th} memory block BLK(z-1) may correspond to a close block CLOSE.

In an embodiment, the bad block management module 1211 may detect a second memory block BLK2 among the memory blocks BLK1 to BLKz included in the first nonvolatile memory device 1110 as the bad block BB.

In an embodiment, if the number of bad blocks BB is two and the number of reserved blocks RB is two, the bad block management module 1211 may control the first nonvolatile memory device 1110 to copy data stored in the second memory block BLK2 corresponding to the bad block BB to the z^{th} memory block BLKz corresponding to the reserved free block, which is a free block among the reserved blocks RB. In an embodiment, when data of the second memory block is copied to the z^{th} memory block BLKz, the z^{th} memory block BLKz may correspond to the close block CLOSE.

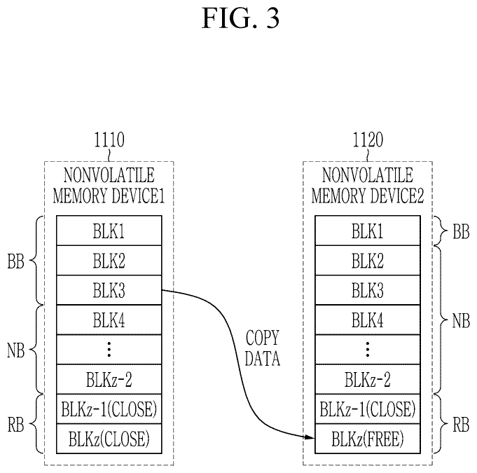

FIG. 3 illustrates a storage device that copies data stored in a bad block of one nonvolatile memory device to a reserved block of another nonvolatile memory device according to an embodiment.

Referring to FIG. 3, a second nonvolatile memory device 1120 may include a plurality of memory blocks BLK1 to BLKz. In an embodiment, the first memory block BLK1 of the second nonvolatile memory device 1120 may be a bad block BB. The second to (z-2)^{th} memory blocks BLK2 to BLK(z-2) of the second nonvolatile memory device 1120 may be normal blocks NB. The (z-1)^{th} to z^{th} memory blocks BLKz-1 to BLKz of the second nonvolatile memory device 1120 may be reserved blocks RB. In an embodiment, the (z-1)^{th} memory block BLK(z-1) may be a close block CLOSE. The (z-1)^{th} memory block BLK(z-1) may be a reserved block RB replaced the first memory block BLK1 of the second nonvolatile memory device 1120.

In an embodiment, the z^{th} memory block BLKz of the second nonvolatile memory device 1120 may be a reserved free block. The z^{th} memory block BLKz may be a reserved block RB that does not store data.

In an embodiment, the bad block management module 1211 may detect one memory block among the memory blocks BLK1 to BLKz included in the first nonvolatile memory device 1110 as a bad block BB, and may copy data stored in one memory block to a reserved free block of another nonvolatile memory device if the number of bad blocks BB of the first nonvolatile memory device 1110 is greater than the number of reserved blocks RB of the first nonvolatile memory device 1110.

In an embodiment, the bad block management module 1211 may detect a third memory block BLK3 among the memory blocks BLK1 to BLKz of the first nonvolatile memory device 1110 as a bad block BB.

In an embodiment, if the number of bad blocks BB of the first nonvolatile memory device 1110 is three and the number of reserved blocks RB of the first nonvolatile memory device 1110 is two, the bad block management module 1211 may control the first to second nonvolatile memory devices 1110 and 1120 to copy data stored in the third memory block BLK3 of the first nonvolatile memory device 1110 to the z^{th} memory block BLKz corresponding to the reserved free block of the second nonvolatile memory device 1120.

In an embodiment, when data stored in the third memory block BLK3 of the first nonvolatile memory device 1110 is copied to the z^{th} memory block BLKz of the second nonvolatile memory device 1120, the z^{th} memory block BLKz of the second nonvolatile memory device 1120 may correspond to a close block CLOSE.

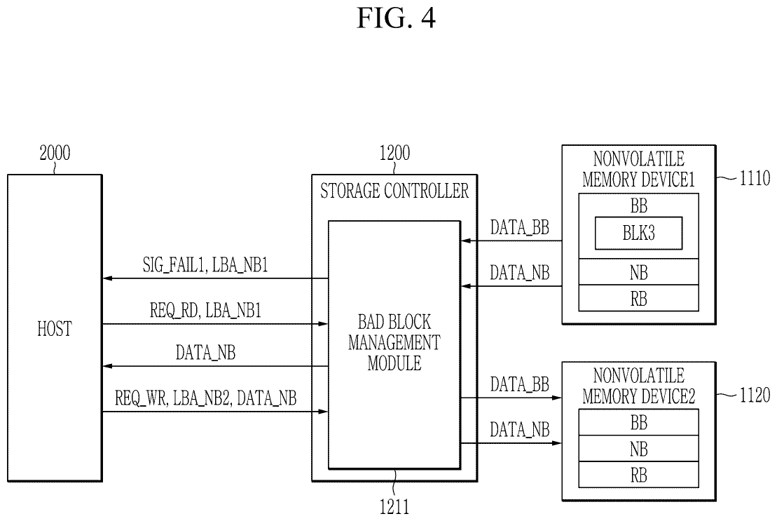

FIG. 4 illustrates a view for describing a storage controller that provides the first level fail signal to the host based on the number of reserved blocks included in a plurality of nonvolatile memory devices according to an embodiment.

Referring to FIG. 4, the bad block management module 1211 may detect one memory block among the memory blocks included in the nonvolatile memory devices as a bad block. In an embodiment, the bad block management module 1211 may copy data DATA_BB stored in the detected bad block to a reserved free block of another nonvolatile memory device if the number of bad blocks of a nonvolatile memory device including the detected bad block is greater than the number of reserved blocks of the nonvolatile memory device including the detected bad block, and the number of reserved free blocks of the remaining nonvolatile memory devices excluding the nonvolatile memory device including the detected bad block among the nonvolatile memory devices is greater than the first preset number of blocks.

In an embodiment, the bad block management module 1211 may detect the third memory block BLK3 of the first nonvolatile memory device 1110 among the memory blocks included in the nonvolatile memory devices as the bad block BB, and if the number of bad blocks BB of the first nonvolatile memory device 1110 is greater than the number of reserved blocks RB of the first nonvolatile memory device 1110, and the second nonvolatile memory device 1120 includes a reserved free block, the bad block management module 1211 may control the first nonvolatile memory device 1110 and the second nonvolatile memory device 1120 to copy the data DATA_BB stored in the third memory block BLK3 of the first nonvolatile memory device 1110 to a reserved free block of the second nonvolatile memory device 1120.

In an embodiment, the bad block management module 1211 may provide a first level fail signal SIG_FAIL1 indicating that a degree of failure of the nonvolatile memory device including the detected bad block is in a first level, and logical addresses corresponding to normal data stored in normal blocks of the nonvolatile memory device including the detected bad block, to the host if the number of bad blocks of the nonvolatile memory device including the detected bad block is greater than the number of reserved blocks of the nonvolatile memory device including the detected bad block, and the number of reserved free blocks of the remaining nonvolatile memory devices is greater than the first preset number of blocks.

For example, the bad block management module 1211 may provide the first level fail signal SIG_FAIL1 indicating that the degree of failure of the nonvolatile memory device including the detected bad block is in the first level, and first logical addresses LBA_NB1 corresponding to normal data DATA_NB stored in normal blocks NB of the first non-volatile memory device 1110, to the host 2000 if the number of bad blocks BB of the first nonvolatile memory device 1110 including the third memory block BLK3 detected as bad blocks is greater than the number of reserved blocks RB of the first nonvolatile memory device 1110, and the second nonvolatile memory device 1120 includes a reserved free block.

In an embodiment, the first level fail signal SIG_FAIL1 may be a signal indicating that more bad blocks BB than the number of reserved blocks RB of the first nonvolatile memory device 1110 have occurred in the first nonvolatile memory device 1110.

In an embodiment, when the first level fail signal SIG_FAIL1 is received, the normal blocks NB of the first nonvolatile memory device 1110 may also become the bad blocks BB, so the host 2000 may determine whether to back up normal data DATA_NB stored in the normal blocks NB of the first nonvolatile memory device 1110 to another nonvolatile memory device.

In an embodiment, the host 2000 may provide a read request REQ_RD requesting the normal data DATA_NB stored in the normal blocks NB in response to the first level fail signal SIG_FAIL1 and first logical addresses LBA_NB1 corresponding to the normal data DATA_NB to the bad block management module 1211.

In an embodiment, the bad block management module 1211 may read the normal data DATA_NB stored in the normal blocks NB of the first non-volatile memory device 1110 in response to the read request REQ_RD, and may provide the normal data DATA_NB to the host 2000.

In an embodiment, the host 2000 may receive the normal data DATA_NB stored in the normal blocks NB of the first non-volatile memory device 1110, and may provide a write request REQ_WR requesting writing of normal data DATA_NB, second logical addresses LBA_NB2, and the normal data DATA_NB to the bad block management module 1211. In an embodiment, the second logical addresses LBA_NB2 may be different from the first logical addresses LBA_NB1.

In an embodiment, when the second logical addresses LBA_NB2 that is different from the first logical addresses LBA_NB1 are provided to the storage controller 1200 together with the normal data DATA_NB, the normal data DATA_NB may be stored in a nonvolatile memory device that is different from the first nonvolatile memory device 1110.

In an embodiment, the bad block management module 1211 may provide the normal data DATA_NB received from the host 2000 based on the second logical addresses LBA_NB2 to the second non-volatile memory device 1120 in response to the write request REQ_WR. In an embodiment, the second nonvolatile memory device 1120 may store the normal data DATA_NB in the normal blocks NB of the second nonvolatile memory device 1120.

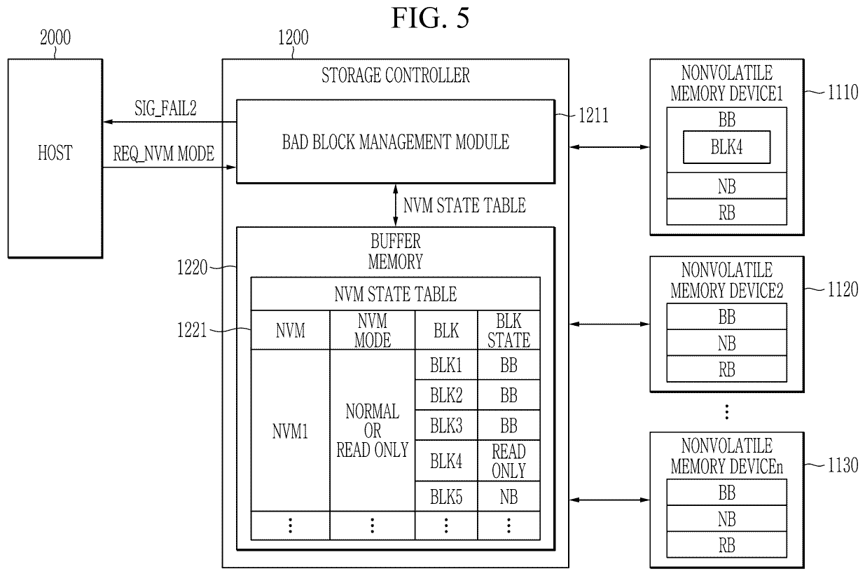

FIG. 5 illustrates a view for describing a storage controller that provides a second level fail signal to the host based on the number of reserved blocks included in a plurality of nonvolatile memory devices according to an embodiment.

Referring to FIG. 5, the bad block management module 1211 may detect one memory block among the memory blocks included in the nonvolatile memory devices as a bad block. In an embodiment, the bad block management module 1211 may set the detected bad block as the read-only block if the number of bad blocks of the nonvolatile memory device including the detected bad block is greater than the number of reserved blocks of the nonvolatile memory device including the detected bad block, and the number of reserved free blocks, which are free blocks among the reserved blocks of the remaining nonvolatile memory devices excluding the nonvolatile memory device including the detected bad block among the nonvolatile memory devices, is less than the first preset number of blocks.

For example, the bad block management module 1211 may detect a fourth memory block BLK4 of the first nonvolatile memory device 1110 among the memory blocks included in the nonvolatile memory devices as the bad block BB. In an embodiment, the bad block management module 1211 may set the fourth memory block BLK4 as a read-only block if the number of bad blocks BB of the first nonvolatile memory device 1110 is greater than the number of reserved blocks RB of the first nonvolatile memory device 1110 and the number of reserved free blocks of the remaining nonvolatile memory devices 1120 to 1130 (i.e., second to n^{th} nonvolatile memory devices) is less than the first preset number of blocks.

Specifically, the bad block management module 1211 may read the NVM state table 1221 from the buffer memory 1220, and may modify information BLK STATE related to a state of the fourth memory block of the first nonvolatile memory device (e.g., NVM1) among information included in the NVM state table 1221 to information READ ONLY indicating that it is a read-only block. For the fourth memory block BLK4 set as a read-only block READ ONLY, only a read operation may be permitted. In an embodiment, a program operation for the fourth memory block (BLK4) set as the read-only block READ ONLY may be prohibited.

In an embodiment, the bad block management module 1211 may provide a second level fail signal SIG_FAIL2 to the host 2000 indicating that the degree of failure of the nonvolatile memory device including the detected bad block is in a second level that is higher than the first level if the number of bad blocks of the nonvolatile memory device including the detected bad block is greater than the number of reserved blocks of the nonvolatile memory device including the detected bad block, and the number of reserved free blocks, which are free blocks among the reserved blocks of the remaining nonvolatile memory devices, is less than the first preset number of blocks.

In the embodiment, the bad block management module 1211 may detect a fourth memory block BLK4 of the first nonvolatile memory device 1110, and if the number of bad blocks BB of the first nonvolatile memory device 1110 is greater than the number of reserved blocks RB of the first nonvolatile memory device 1110 and the number of reserved free blocks of the remaining nonvolatile memory devices 1120 to 1130 is less than the first preset number of blocks, may provide the second level fail signal SIG_FAIL2 to the host 2000 indicating that the degree of failure of the first nonvolatile memory device 1110 is in the second level.

In an embodiment, the second level fail signal SIG_FAIL2 may be a signal notifying that more bad blocks BB have occurred in the first non-volatile memory device 1110 than when the first level fail signal SIG_FAIL1 was provided to the host 2000.

In an embodiment, when the second level fail signal SIG_FAIL2 is received, the host 2000 may determine an operation mode of the first nonvolatile memory device 1110 to be a normal mode or a read-only mode. In an embodiment, the host 2000 may provide an operation mode setting request REQ_NVM MODE to the bad block management module 1211 in response to the second level fail signal SIG_FAIL2. In an embodiment, the operation mode setting request REQ_NVM MODE may include information regarding the operation mode of the first nonvolatile memory device 1110. In an embodiment, information related to the operating mode may include information related to the normal mode or the read-only mode.

In an embodiment, the bad block management module 1211 may read the NVM state table 1221 in response to the operation mode setting request REQ_NVM MODE received from the host 2000. In an embodiment, the bad block management module 1211 may modify operation mode information NVM MODE of the first nonvolatile memory device to a normal mode NORMAL or a read-only mode READ ONLY based on the information related to the operation mode included in the operation mode setting request REQ_NVM MODE. In an embodiment, when the operation mode information NVM MODE of the first nonvolatile memory device is modified to the read-only mode READ ONLY, a read operation may be permitted for the operation of the first nonvolatile memory device 1110, and a program operation may be prohibited.

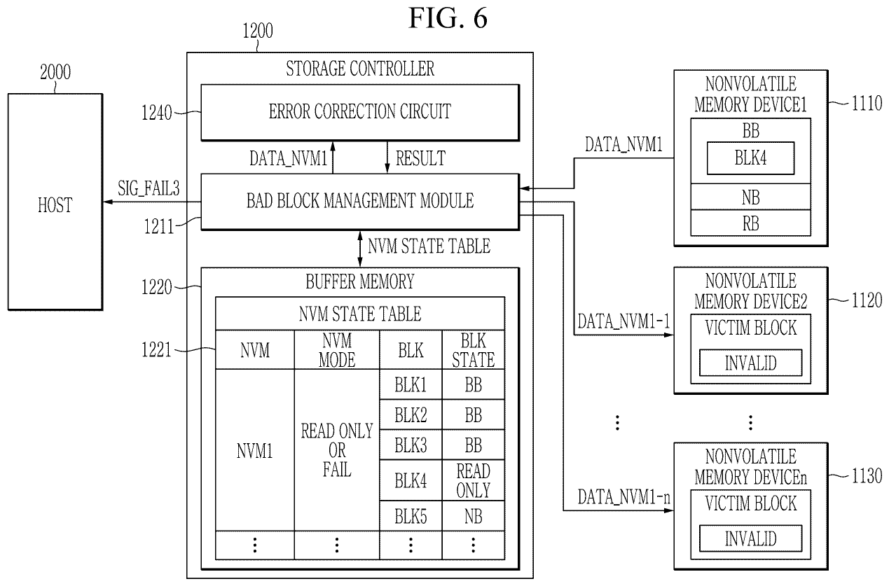

FIG. 6 illustrates a view for describing a storage controller that provides a third level fail signal to the host based on the number of error bits included in memory blocks of a nonvolatile memory device according to an embodiment.

Referring to FIG. 6, the bad block management module 1211 may detect one memory block among the memory blocks included in the nonvolatile memory devices as a bad block. In an embodiment, the bad block management module 1211 may read data stored in the nonvolatile memory device including the detected bad block if the number of bad blocks of the nonvolatile memory device including the detected bad block is greater than the number of reserved blocks of the nonvolatile memory device including the detected bad block, and the number of reserved free blocks, which are free blocks among the reserved blocks of the remaining nonvolatile memory devices, is less than the first preset number of blocks.

In the embodiment, the bad block management module 1211 may detect a fourth memory block BLK4 of the first nonvolatile memory device 1110 as the bad block BB, and if the number of bad blocks BB of the first nonvolatile memory device 1110 is greater than the number of reserved blocks RB of the first nonvolatile memory device 1110 and the number of reserved free blocks of the remaining nonvolatile memory devices 1120 to 1130 is less than the first preset number of blocks, may read data DATA_NVM1 stored in the memory blocks of the first nonvolatile memory device 1110. The memory blocks of the first non-volatile memory device 1110 may include the fourth memory block BLK4, the normal blocks NB, and the reserved blocks RB.

In an embodiment, the bad block management module 1211 may receive the data DATA_NVM1 of the first nonvolatile memory device, and may provide the data DATA_NVM1 of the first nonvolatile memory device to the error correction circuit 1240. In an embodiment, the error correction circuit 1240 may perform an error correction operation to correct error bits included in the data DATA_NVM1 of the first nonvolatile memory device. In an embodiment, the error correction circuit 1240 may provide a result RESULT of the error correction operation on the data DATA_NVM1 of the first nonvolatile memory device to the bad block management module 1211.

In an embodiment, the bad block management module 1211 may determine memory blocks including more error bits than the preset number of error bits among the memory blocks of the first nonvolatile memory device 1110 based on the result RESULT of the error correction operation.

In an embodiment, among the memory blocks of the first nonvolatile memory device 1110, memory blocks including more error bits than the preset number of error bits may be memory blocks storing data in which an error correction operation for data read from the first nonvolatile memory device 1110 using a hard-decision read voltage has failed and an error correction operation for data read from the first nonvolatile memory device 1110 has passed using a soft-decision read voltage. In an embodiment, among the memory blocks of the first nonvolatile memory device 1110, memory blocks including more error bits than the preset number of error bits may be memory blocks in which data is stored for which an error correction operation for data read from the first nonvolatile memory device 1110 using a default read voltage has failed and an error correction operation for data read from the first nonvolatile memory device 1110 has passed by a read retry operation or an on-chip valley search operation.

In an embodiment, the bad block management module 1211 may provide a third level signal SIG_FAIL3 indicating that the degree of failure of the first nonvolatile memory device 1110 is in a third level that is higher than the second level, to the host 2000, if the number of memory blocks including error bits greater than the preset number of error bits among the memory blocks of the first nonvolatile memory device 1110 is greater than a second preset number of blocks. For example, the second preset number of blocks may be different from the first preset number of blocks, but the present invention is not limited thereto.

Specifically, the bad block management module 1211 may provide the third level fail signal SIG_FAIL3 indicating that the first nonvolatile memory device 1110 enters a fail mode FAIL to the host 2000 when the number of memory blocks including error bits greater than the preset number of error bits among the memory blocks of the first nonvolatile memory device 1110 is greater than the second preset number of blocks and a magnitude of free space of remaining nonvolatile memory devices 1120 to 1130 is greater than a magnitude of the data DATA_NVM1 of the first nonvolatile memory device.

In an embodiment, the bad block management module 1211 may set the first nonvolatile memory device 1110 as a fail memory device if the number of memory blocks including error bits greater than the preset number of error bits among the memory blocks of the first nonvolatile memory device 1110 is greater than the second preset number of blocks and the magnitude of free space of the remaining nonvolatile memory devices 1120 to 1130 is greater than the size of the data DATA_NVM1 of the first nonvolatile memory device.

Specifically, the bad block management module 1211 may read the NVM state table 1221 from the buffer memory 1220, and may modify information NVM MODE regarding the mode of the first nonvolatile memory device among the information included in the NVM state table 1221 to the fail mode FAIL.

In an embodiment, the magnitude of the free space of the remaining nonvolatile memory devices 1120 to 1130 may correspond to the number of free blocks among the memory blocks of the remaining nonvolatile memory devices 1120 to 1130. In an embodiment, the magnitude of the free space of the remaining nonvolatile memory devices 1120 to 1130 may correspond to the number of victim blocks VICTIM BLOCK in which invalid data INVALID is stored among the memory blocks of the remaining nonvolatile memory devices.

In an embodiment, the bad block management module 1211 may provide a third level fail signal SIG_FAIL3 indicating that the first nonvolatile memory device 1110 enters a fail mode to the host 2000 if the number of memory blocks including error bits greater than the preset number of error bits among the memory blocks of the first nonvolatile memory device 1110 is greater than the second preset number of blocks and the number of victim blocks VICTIM BLOCK in which the invalid data INVALID is stored among the memory blocks of the remaining nonvolatile memory devices 1120 to 1130 is greater than the first preset number of blocks.

In an embodiment, the bad block management module 1211 may perform a garbage collection operation on the victim blocks VICTIM BLOCK if the number of victim blocks VICTIM BLOCK storing the invalid data INVALID among the memory blocks of the remaining nonvolatile memory devices 1120 to 1130 is greater than the first preset number of blocks. In an embodiment, the bad block management module 1211 may erase the invalid data INVALID stored in the victim blocks VICTIM BLOCK while performing the garbage collection operation.

In an embodiment, the bad block management module 1211 may perform the garbage collection operation, and then may copy the data DATA_NVM1 of the first nonvolatile memory device to the victim blocks VICTIM BLOCK of the remaining nonvolatile memory devices 1120 to 1130. In an embodiment, the data DATA_NVM1 of the first nonvolatile memory device may include first data DATA_NVM1-1 to n^{th} DATA_NVM1-n. In an embodiment, the bad block management module 1211 may provide the first data DATA_NVM1-1 to n^{th} DATA_NVM1-n to the second to n^{th} nonvolatile memory devices 1120 to 1130, respectively. In an embodiment, the second to n^{th} nonvolatile memory devices 1120 to 1130 may store the first to n^{th} data DATA_NVM(1-1) to DATANVM(1-n) in the victim blocks VICTIM BLOCK.

In an embodiment, the bad block management module 1211 may provide the third level fail signal SIG_FAIL3 indicating that the first nonvolatile memory device 1110 enters a read-only mode READ ONLY to the host 2000 when the number of memory blocks including error bits greater than the preset number of error bits among the memory blocks of the first nonvolatile memory device 1110 is greater than the second preset number of blocks and a magnitude of free space of remaining nonvolatile memory devices 1120 to 1130 is less than a magnitude of the data DATA_NVM1 of the first nonvolatile memory device.

In an embodiment, the bad block management module 1211 may provide a third level fail signal SIG_FAIL3 indicating that the first nonvolatile memory device 1110 enters a read-only mode READ ONLY to the host 2000 when the number of memory blocks including error bits greater than the preset number of error bits among the memory blocks of the first nonvolatile memory device 1110 is greater than the second preset number of blocks and the number of victim blocks VICTIM BLOCK in which the invalid data INVALID is stored among the memory blocks of the remaining nonvolatile memory devices 1120 to 1130 is less than the first preset number of blocks.

In an embodiment, the bad block management module 1211 may set the first nonvolatile memory device 1110 to a read-only mode memory device (or read-only memory device) if the number of memory blocks including error bits greater than the preset number of error bits among the memory blocks of the first nonvolatile memory device 1110 is greater than the first preset number of blocks and the magnitude of free space of the remaining nonvolatile memory devices 1120 to 1130 is less than the magnitude of data DATA_NVM1 of the first nonvolatile memory device.

Specifically, the bad block management module 1211 may read the NVM state table 1221 from the buffer memory 1220, and may modify information NVM MODE regarding the mode of the first nonvolatile memory device among the information included in the NVM state table 1221 to the read-only mode READ ONLY.

In an embodiment, the storage device 1000 may detect a bad block among the memory blocks, and may determine a possibility that the nonvolatile memory device including the detected bad block will be failed as a first level based on the number of bad blocks of the nonvolatile memory device including the detected bad block.

In an embodiment, the storage device 1000 may determine a second level of possibility that a nonvolatile memory device including a detected bad block will be failed based on the number of reserved free blocks of the remaining nonvolatile memory devices excluding the nonvolatile memory device including the detected bad block.

In an embodiment, the storage device 1000 may determine a third level of possibility that the nonvolatile memory device including the detected bad block will be failed based on the number of memory blocks of the nonvolatile memory device including the detected bad block that include more error bits than the preset number of error bits.

In an embodiment, the storage device 1000 may increase a period of time during which the nonvolatile memory device including the detected bad block can be used by gradually determining a possibility that the nonvolatile memory device including the detected bad block will be failed based on the number of bad blocks of the nonvolatile memory device including the detected bad block, the number of reserved free blocks of the remaining nonvolatile memory devices, and the number of memory blocks including more error bits than the preset number of error bits among the memory blocks of the nonvolatile memory device including the detected bad block.

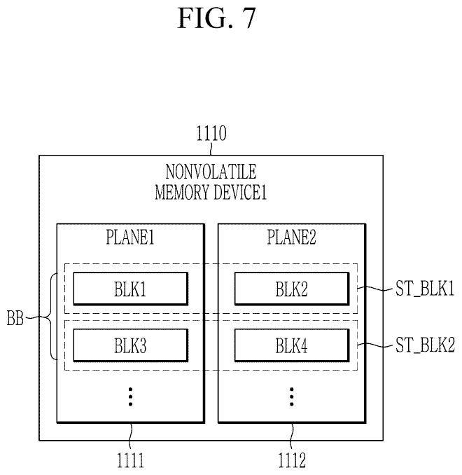

FIG. 7 illustrates a view for describing a stripe block included in one nonvolatile memory device according to an embodiment.

FIG. 7 will be described with referring to FIG. 6. Referring to FIGS. 6 and 7, the first nonvolatile memory device 1110 may include a first plane 1111 and a second plane 1112. The first plane 1111 may include a first memory block BLK1 and a third memory block BLK3. The second plane 1112 may include a second memory block BLK2 and a fourth memory block BLK4. The first memory block BLK1, the second memory block BLK2, and the third memory block BLK3 may be memory blocks detected as bad blocks BB.

In an embodiment, a stripe block may include memory blocks contained in different planes. In an embodiment, a first stripe block ST_BLK1 may include the first memory block BLK1 and the second memory block BLK2. In the embodiment, the second stripe block ST_BLK2 may include the third memory block BLK3 and the fourth memory block BLK4. In an embodiment, a stripe block may be a unit that performs a sequential program operation or a sequential read operation.

In an embodiment, the bad block management module 1211 may detect the fourth memory block BLK4 as a bad block after the first to third memory blocks BLK1 to BLK3 are detected as bad blocks BB. In an embodiment, the bad block management module 1211 may determine whether a second stripe block ST_BLK2 includes another bad block BB other than the fourth memory block BLK4 if the number of bad blocks BB of the first nonvolatile memory device 1110 is greater than the number of reserved blocks RB of the first nonvolatile memory device 1110 and the number of reserved free blocks of the remaining nonvolatile memory devices 1120 to 1130 is less than the first preset number of blocks.

In an embodiment, the second stripe block ST_BLK2 may include a third memory block BLK3 that is the bad block BB in addition to the fourth memory block BLK4, so the bad block management module 1211 may provide the third level fail signal SIG_FAIL3 to the host 2000 indicating that the degree of failure of the first nonvolatile memory device 1110 is in the third level.

In an embodiment, the bad block management module 1211 may provide the third level fail signal SIG_FAIL3 indicating that the first nonvolatile memory device 1110 enters a fail mode FAIL to the host 2000 if the second stripe block ST_BLK2 includes a bad block other than the detected bad block and the magnitude of the free space of the remaining nonvolatile memory devices 1120 to 1130 is greater than the magnitude of the data DATA_NVM1 of the first nonvolatile memory device.

In an embodiment, the bad block management module 1211 may copy the data DATA_NVM1 of the first nonvolatile memory device 1110 to the remaining nonvolatile memory devices 1120 to 1130 when the first nonvolatile memory device 1110 enters the fail mode FAIL.

In an embodiment, the bad block management module 1211 may provide the third level fail signal SIG_FAIL3 indicating that the first nonvolatile memory device 1110 enters a read-only mode READ ONLY to the host 2000 if the second stripe block ST_BLK2 includes a bad block other than the detected bad block and the magnitude of the free space of the remaining nonvolatile memory devices 1120 to 1130 is less than the magnitude of the data DATA_NVM1 of the first nonvolatile memory device.

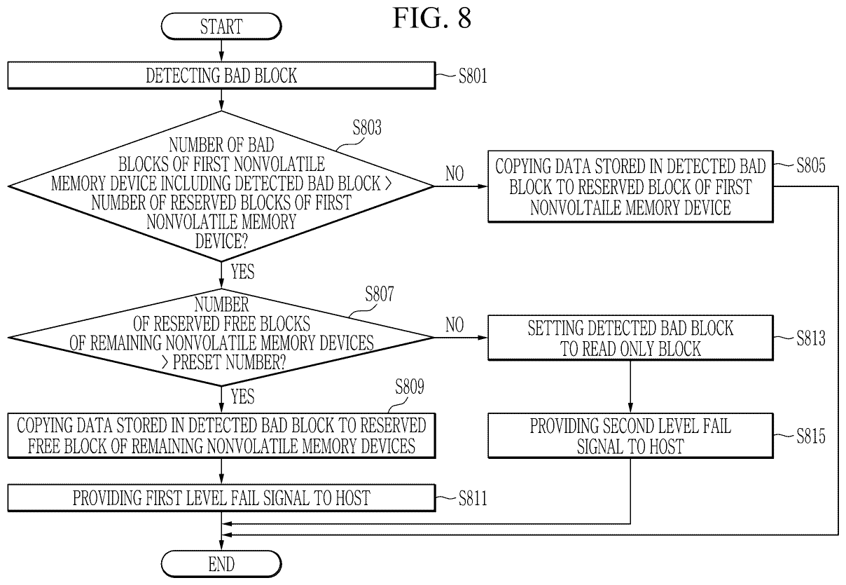

FIG. 8 illustrates a flowchart showing a storage device providing a first level fail signal and a second level fail signal to the host according to an embodiment.

Referring to FIG. 8, in S801, the storage device 1000 may detect a bad block.

In S803, the storage device 1000 may compare whether the number of bad blocks of the first nonvolatile memory device including the detected bad block is greater than the number of reserved blocks of the first nonvolatile memory device including the detected bad block. In an embodiment, S805 may be performed if the number of bad blocks of the first nonvolatile memory device is equal to or less than the number of reserved blocks of the first nonvolatile memory device. In an embodiment, S807 may be performed if the number of bad blocks of the first nonvolatile memory device is greater than the number of reserved blocks of the first nonvolatile memory device.

In S805, the storage device 1000 may copy data stored in the detected bad block to a reserved block of the first nonvolatile memory device if the number of bad blocks of the first nonvolatile memory device including the detected bad block is equal to or less than the number of reserved blocks of the first nonvolatile memory device.

In S807, if the number of bad blocks of the first nonvolatile memory device including the detected bad block is greater than the number of reserved blocks of the first nonvolatile memory device, the storage device 1000 may determine whether the number of reserved free blocks of the remaining nonvolatile memory devices excluding the first nonvolatile memory device among the nonvolatile memory devices is greater than the first preset number of blocks. In an embodiment, a reserved free block may be a free block in which no data is stored among the reserved blocks. In an embodiment, if the number of reserved free blocks of the remaining nonvolatile memory devices is greater than the first preset number of blocks, S809 may be performed. In an embodiment, if the number of reserved free blocks of the remaining nonvolatile memory devices is less than the first preset number of blocks, S813 may be performed.

In S809, the storage device 1000 may copy data stored in a detected bad block to a reserved free block of the remaining nonvolatile memory devices if the number of reserved free blocks of the remaining nonvolatile memory devices is greater than the first preset number of blocks.

In S811, the storage device 1000 may provide the first level fail signal to the host 2000. In an embodiment, the first level fail signal may be a signal indicating that the number of bad blocks of the first nonvolatile memory device including the detected bad block is greater than the number of reserved blocks of the first nonvolatile memory device. In an embodiment, the host 2000 may determine whether to back up normal data stored in normal blocks of the first nonvolatile memory device including the bad block detected based on the first level fail signal to another nonvolatile memory device. In an embodiment, the host 2000 may provide, to the storage device, second logical addresses that are different from the first logical addresses corresponding to data stored in normal blocks of the first nonvolatile memory device, normal data of the first nonvolatile memory device, and a write request in response to the first level fail signal. The storage device 1000 may store normal data in another nonvolatile memory device other than the first nonvolatile memory device in response to the write request.

In S813, the storage device 1000 may set a detected bad block as a read-only block if the number of reserved free blocks of the remaining non-volatile memory devices is less than the first preset number of blocks. In an embodiment, if a detected bad block is set as a read-only block, an program operation on the detected bad block may be restricted.

In S815, the storage device 1000 may provide the second level fail signal to the host 2000. This may be a signal indicating that more bad blocks have occurred in the first nonvolatile memory device than when the first level fail signal was provided to the host 2000. In an embodiment, the host 2000 may determine an operating mode of the first nonvolatile memory device including a bad block detected based on the second level fail signal to be a normal mode or a read-only mode. In an embodiment, the host 2000 may provide a request to the storage device 1000 to set an operation mode for the first nonvolatile memory device in response to the second level fail signal. The storage device 1000 may set the operation mode of the first nonvolatile memory device to the normal mode or read-only mode in response to the operation mode setting request. In an embodiment, when the operation mode of the first nonvolatile memory device is set to the read-only mode, a program operation for the first nonvolatile memory device may be restricted.

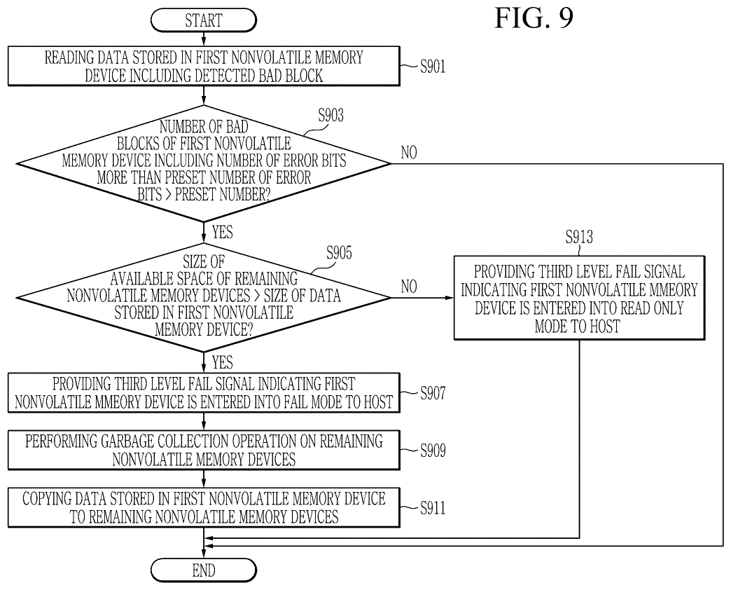

FIG. 9 illustrates a flowchart showing a storage device providing a third level fail signal to the host according to an embodiment.

Referring to FIG. 9, S901 may be performed after S815 of FIG. 8. In S901, the storage device 1000 may read data stored in the first nonvolatile memory device if the number of bad blocks of the first nonvolatile memory device including the detected bad block is greater than the number of reserved blocks of the first nonvolatile memory device and the number of reserved free blocks of the remaining nonvolatile memory devices is less than the first preset number of blocks.

In S903, the storage device 1000 may determine whether the number of memory blocks of the first nonvolatile memory device that include more error bits than a preset number of error bits is greater than the second preset number of blocks. In an embodiment, S905 may be performed if the number of memory blocks including error bits greater than the preset number of error bits is greater than the second preset number of blocks. In an embodiment, the operation may be terminated if the number of memory blocks including more error bits than the preset number of error bits is less than the second preset number of blocks.

In S905, the storage device 1000 may determine whether the size of free space of the remaining nonvolatile memory devices is greater than the magnitude of data stored in the first nonvolatile memory device if the number of memory blocks including error bits greater than the preset number of error bits is greater than the second preset number of blocks. In an embodiment, S907 may be performed if the magnitude of free space of the remaining nonvolatile memory devices is greater than the magnitude of data stored in the first nonvolatile memory device. In an embodiment, S913 may be performed if the magnitude of free space of the remaining nonvolatile memory devices is less than the magnitude of data stored in the first nonvolatile memory device. In an embodiment, the magnitude of the free space of the remaining nonvolatile memory devices may correspond to the number of victim blocks in which invalid data is stored among the memory blocks of the remaining nonvolatile memory devices.

In S907, the storage device 1000 may provide the third level fail signal to the host indicating that the first nonvolatile memory device enters a fail mode if the magnitude of the free space of the remaining nonvolatile memory devices is greater than the magnitude of the data stored in the first nonvolatile memory device. In an embodiment, the storage device 1000 may set the operation mode of the first nonvolatile memory device to a fail mode if the magnitude of free space of the remaining nonvolatile memory devices is greater than the magnitude of the data stored in the first nonvolatile memory device.

In S909, the storage device 1000 may perform a garbage collection operation on the remaining non-volatile memory devices. In an embodiment, the storage device 1000 may perform an erase operation on victim blocks storing invalid data while performing the garbage collection operation.

In S911, the storage device 1000 may copy the data stored in the first nonvolatile memory device to the remaining nonvolatile memory devices. For example, the storage device 1000 may copy the data stored in the first nonvolatile memory device to the victim blocks in the remaining nonvolatile memory devices.

In S913, the storage device 1000 may provide the third level fail signal to the host indicating that the first nonvolatile memory device enters a read-only mode if the magnitude of the free space of the remaining nonvolatile memory devices is less than the magnitude of the data stored in the first nonvolatile memory device. In an embodiment, the storage device 1000 may set the operation mode of the first nonvolatile memory device to a read-only mode if the magnitude of free space of the remaining nonvolatile memory devices is less than the magnitude of the data stored in the first nonvolatile memory device.

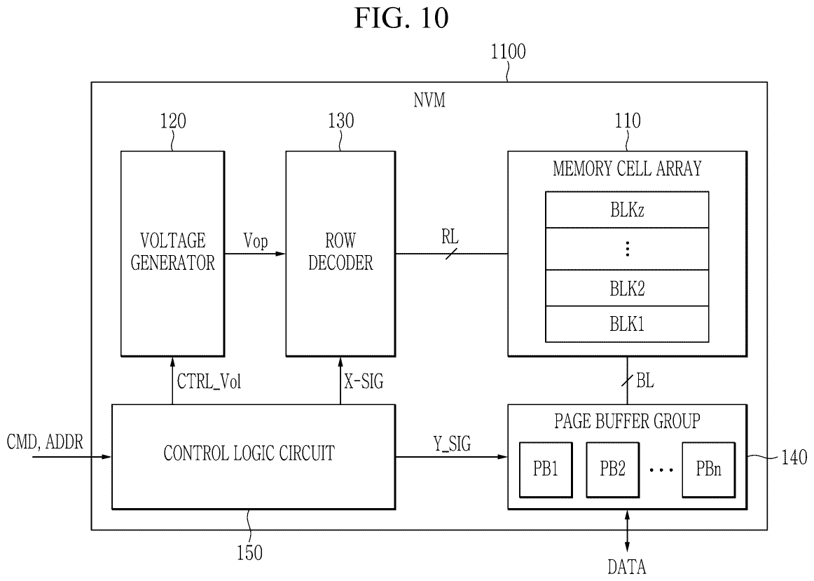

FIG. 10 illustrates a view for describing a nonvolatile memory device 1100 according to an embodiment.

Referring to FIG. 10, the nonvolatile memory device 1100 may include a memory cell array 110, a voltage generator 120, a row decoder 130, a page buffer group 140, and a control logic circuit 150. The nonvolatile memory device 1100 of FIG. 10 may be one of the nonvolatile memory devices described above with reference to FIGS. 1 to 7.

The memory cell array 110 may include a plurality of memory blocks BLK1 to BLKz. The memory blocks BLK1 to BLKz may be connected to the row decoder 130 through row lines RL. The memory blocks BLK1 to BLKz may be connected to the page buffer group 140 through bit lines BL. Each of the memory blocks BLK1 to BLKz may include a plurality of memory cells. In an embodiment, a memory cell of the memory cell array 110 may be a nonvolatile memory cell. In an embodiment, the memory blocks BLK1 to BLKz may include bad blocks, normal blocks, and reserved blocks.

The voltage generator 120 may generate operating voltages Vop using an external power voltage supplied to the nonvolatile memory device 1100. The voltage generator 120 may operate in response to a control signal CTRL_Vol from the control logic circuit 150.

In an embodiment, the voltage generator 120 may generate the operating voltages Vop used for program operations, read operations, and erase operations. For example, the voltage generator 120 may generate a program voltage, a pass voltage, a read voltage, and an erase voltage. The operating voltages Vop may be supplied to the memory cell array 110 by the row decoder 130.

The row decoder 130 may be connected to the memory cell array 110 via the row lines RL. The row lines RL may include string selection lines, word lines, and ground selection lines.

The row decoder 130 may operate in response to a row address signal from the control logic circuit 150. The low decoder 130 may receive a row address signal X_SIG from the control logic circuit 150. In an embodiment, the row decoder 130 may select at least one word line among the word lines based on the row address signal X_SIG, and may apply the operating voltages Vop provided from the voltage generator 120 to at least one word line.

In an embodiment, the row decoder 130 may apply the program voltage to a selected word line among the word lines during the program operation, and may apply the pass voltage at a level lower than the program voltage to unselected word lines. The row decoder 130 may apply a verification voltage to a selected word line during a program verification operation and apply a verification pass voltage at a level that is higher than a verification voltage to the unselected word lines.

The row decoder 130 may apply the read voltage to the selected word line during the read operation, and may apply the read pass voltage at a level higher than the read voltage to the unselected word lines.

The page buffer group 140 may include a plurality of page buffers PB1 to PBn (herein, n is a natural number of 2 or greater). The plurality of page buffers PB1 to PBn may be respectively connected to a plurality of memory cells included in the memory cell array 110 through the bit lines BL. The plurality of page buffers PB1 to PBn may operate in response to a column address signal Y_SIG from the control logic circuit 150.

In an embodiment, the plurality of page buffers PB1 to PBn may receive data DATA from the storage controller 1200. The plurality of page buffers PB1 to PBn may select at least one bit line among the bit lines BL based on the column address signal Y_SIG received from the control logic 150.

In an embodiment, the plurality of page buffers PB1 to PBn may transfer data received from the storage controller 1200 to a plurality of memory cells of the memory cell array 110 through the bit lines BL during the program operation. The memory cells may be programmed according to received data. The plurality of page buffers PB1 to PBn may sense data stored in the memory cells through the bit lines BL during the program verification operation.

The plurality of page buffers PB1 to PBn may sense data stored in the memory cells through the bit lines BL during the read operation, and may temporarily store the sensed data in the plurality of page buffers PB1 to PBn.

The control logic circuit 150 may be connected to the voltage generator 120, the row decoder 130, and the page buffer group 140.

The control logic circuit 150 may control an overall operation of the nonvolatile memory device 1100. The control logic circuit 150 may control the voltage generator 120, the row decoder 130, and the page buffer group 140 to perform an operation in response to the command received from the storage controller 1200.

While this disclosure has been described in connection with what is presently considered to be practical embodiments, it is to be understood that the present invention is not limited to the disclosed embodiments, but, on the contrary, is intended to cover various modifications and equivalent dispositions included within the spirit and scope of the appended claims.

What is claimed is:

1. A storage device comprising:
a plurality of nonvolatile memory devices including a plurality of memory blocks; and
a storage controller connected to the plurality of nonvolatile memory devices and configured to:
detect a bad block among the plurality of memory blocks,
generate a first level fail signal indicating that a degree of failure of a first nonvolatile memory device including the bad block among the plurality of nonvolatile memory devices is in a first level based on the number of bad blocks of the first nonvolatile memory device,
generate a second level fail signal indicating that the degree of failure of the first nonvolatile memory device is in a second level that is higher than the first level based on the number of reserved free blocks, which are free blocks, among reserved blocks included in the remaining nonvolatile memory devices among the plurality of nonvolatile memory devices,
generate a third level fail signal indicating that the degree of failure of the first nonvolatile memory device is in a third level that is higher than the second level based on the number of memory blocks including error bits greater than a preset number of error bits among memory blocks included in the first nonvolatile memory device, and
provide the first level fail signal, the second level fail signal, or the third level fail signal to a host outside the storage device.

2. The storage device of claim 1, wherein the storage controller is configured to provide the first level fail signal to the host when the number of bad blocks of the first nonvolatile memory device is greater than the number of reserved blocks included in the first nonvolatile memory device and the number of reserved free blocks included in the remaining nonvolatile memory devices is greater than a preset number of blocks.

3. The storage device of claim 2, wherein the storage controller is configured to:
provide the host with a first logical address corresponding to first data stored in a normal block of the first nonvolatile memory device and the first level fail signal, and
provide the first data to the host in response to a read request received from the host.

4. The storage device of claim 3, wherein the storage controller is configured to:
receive the first data and a second logical address corresponding to the first data and different from the first logical address from the host, and
store the first data in a second nonvolatile memory device among the nonvolatile memory devices based on the second logical address.

5. The storage device of claim 1, wherein the storage controller is configured to control the plurality of nonvolatile memory devices to copy data stored in the bad block to the reserved free blocks included in the remaining nonvolatile memory devices when the number of bad blocks of the first nonvolatile memory device is greater than the number of reserved blocks included in the first nonvolatile memory device and the number of reserved free blocks included in the remaining nonvolatile memory devices is greater than a preset number of blocks.

6. The storage device of claim 1, wherein the storage controller is configured to provide the second level fail signal to the host when the number of bad blocks of the first nonvolatile memory device is greater than the number of reserved blocks included in the first nonvolatile memory device and the number of reserved free blocks included in the remaining nonvolatile memory devices is smaller than a preset number of blocks.

7. The storage device of claim 6, wherein the storage controller is configured to set the first nonvolatile memory device as a read-only memory device in response to a mode setting request received from the host after providing the second level fail signal to the host.

8. The storage device of claim 1, wherein the storage controller is configured to set the bad block as a read-only block when the number of bad blocks of the first nonvolatile memory device is greater than the number of reserved blocks included in the first nonvolatile memory device and the number of reserved free blocks included in the remaining nonvolatile memory devices is smaller than a preset number of blocks.

9. The storage device of claim 1, wherein the storage controller is configured to provide the host with the third level fail signal indicating that the first nonvolatile memory device enters a read-only mode or a fail mode when the number of the memory blocks including error bits greater than the preset number of error bits among the memory blocks included in the first nonvolatile memory device is greater than a second preset number of blocks.

10. The storage device of claim 9, wherein the storage controller is configured to control the plurality of nonvolatile memory devices to perform a garbage collection operation on victim blocks in the remaining nonvolatile memory devices, when the number of victim blocks storing invalid data among memory blocks included in the remaining nonvolatile memory devices is greater than a first preset number of blocks different from the second preset number of blocks, and copy data stored in the first nonvolatile memory device to the victim blocks.

11. The storage device of claim 9, wherein the storage controller is configured to set the first nonvolatile memory device as a read-only memory device when the number of victim blocks storing invalid data among memory blocks included in the remaining nonvolatile memory devices is smaller than the first preset number of blocks different from the second preset number of blocks.

12. An electronic system comprising:
a host; and
a storage device connected to the host, including a plurality of nonvolatile memory devices, and configured to:
output a first level fail signal indicating that a possibility of failure of a first nonvolatile memory device among the plurality of nonvolatile memory devices is in a first level when the number of bad blocks included in the first nonvolatile memory device is greater than the number of reserved blocks included in the first nonvolatile memory device,
output a second level fail signal indicating that the possibility of failure of the first nonvolatile memory device is in a second level higher than the first level when the number of reserved free blocks included in the remaining nonvolatile memory devices among the plurality of nonvolatile memory devices is less than a first preset number of blocks, and
output a third level fail signal indicating that the possibility of failure of the first nonvolatile memory device is in a third level higher than the second level when the number of memory blocks including more error bits than a preset number of error bits among memory blocks included in the first nonvolatile memory device is greater than a second preset number of blocks different from the first preset number of blocks,
wherein the host is configured to control the storage device based on the first level fail signal, the second level fail signal, or the third level fail signal.

13. The electronic system of claim 12, wherein the host is configured to:
receive the first level fail signal and a first logical address corresponding to first data stored in a normal block of the first nonvolatile memory device, and
provide a write request requesting writing of the first data and a second logical address that is different from the first logical address to the storage device, and
wherein the storage device is configured to store the first data in a second nonvolatile memory device among the plurality of nonvolatile memory devices in response to the write request.

14. The electronic system of claim 12, wherein in response to the second level fail signal, the host is configured to provide a mode setting request to set an operating mode of the first nonvolatile memory device to a read-only mode or a normal mode to the storage device.

15. The electronic system of claim 12, wherein the storage device is configured to provide the host with the third level fail signal indicating that the first nonvolatile memory device enters a fail mode when the number of memory blocks including error bits greater than the preset number of error bits among the memory blocks included in the first nonvolatile memory device is greater than the second preset number of blocks, and the number of victim blocks storing invalid data among memory blocks included in the remaining nonvolatile memory devices is greater than the first preset number of blocks.

16. The electronic system of claim 12, wherein the storage device is configured to provide the host with the third level fail signal indicating that the first nonvolatile memory device enters a read-only mode when the number of memory blocks including error bits greater than the preset number of error bits among the memory blocks included in the first nonvolatile memory device is greater than the second preset number of blocks and the number of victim blocks storing invalid data among memory blocks included in remaining nonvolatile memory devices is less than the first preset number of blocks.

17. A storage controller comprising:
a memory interface configured to communicate with a plurality of nonvolatile memory devices including a plurality of memory blocks; and
a bad block management module connected to the plurality of nonvolatile memory devices and configured to:
detect a bad block among the plurality of memory blocks,
copy data stored in the bad block to reserved free blocks of the remaining nonvolatile memory devices among the plurality of nonvolatile memory devices when the number of bad blocks of a first nonvolatile memory device including the bad block among the plurality of nonvolatile memory devices is greater than the number of reserved blocks of the first nonvolatile memory device,
set the bad block as a read-only block when the number of reserved free blocks of the remaining volatile memory devices is less than a first threshold number, and
set a mode of the first nonvolatile memory device to a read-only mode or a fail mode when the number of memory blocks including more error bits than a preset number of error bits among memory blocks included in the first nonvolatile memory device is greater than a second threshold number.

18. The storage controller of claim 17, wherein the bad block management module is configured to provide a first level fail signal and a first logical address corresponding to first data stored in a normal block of the first nonvolatile memory device to a host outside the storage controller when the number of bad blocks of the first nonvolatile memory device is greater than the number of the reserved blocks of the first nonvolatile memory device and the number of the reserved free blocks of the remaining nonvolatile memory devices is greater than the first threshold number.

19. The storage controller of claim 17, wherein the bad block management module is configured to:
provide a second level fail signal to a host outside the storage controller when the number of the reserved free blocks of the remaining nonvolatile memory devices is less than the first threshold number, and
receive information related to an operation mode of the first nonvolatile memory device from the host.

20. The storage controller of claim 17, wherein the bad block management module is configured to:
provide a third level fail signal to a host outside the storage controller when the number of the memory blocks including error bits greater than the preset number of error bits among the memory blocks included in the first nonvolatile memory device is greater than the second threshold number, and
control the nonvolatile memory devices to copy data stored in the first nonvolatile memory device to the remaining nonvolatile memory devices.
